(19) United States
(12) Patent Application Publication
(10) Pub. No.: US 2007/0287202 A1
(43) Pub. Date: Dec. 13, 2007

(54) Method for Producing Nano-Scale Low-Dimensional Quantum Structure, and Method for Producing Integrated Circuit Using the Method for Producing the Structure

(76) Inventors: Kenzo Maehashi, Osaka (JP); Yasuyuki Fujiwara, Osaka (JP); Koichi Inoue, Hyogo (JP); Kazuhiko Matsumoto, Osaka (JP); Yasuhide Ohno, Osaka (JP)

Correspondence Address: HARNESS, DICKEY & PIERCE, P.L.C., P.O. BOX 8910, RESTON, VA, 20195, US

(21) Appl. No.: 11/660,931

(22) PCT Filed: Aug. 30, 2005
(86) PCT No.: PCT/JP05/15776

§ 371 Date: Feb. 23, 2007

(30) Foreign Application Priority Data
Aug. 31, 2004 (JP) 2004-253518

(51) Int. Cl. H01L 21/71; C25B 5/00

(52) U.S. Cl. 438/10; 204/156; 257/E21.528; 977/844; 977/881; 977/932

(57) ABSTRACT

A method of an embodiment of the present of the present application is for producing a nano-scale low dimensional quantum structure. The method includes: bringing a catalyst on a substrate into contact with vaporized carbon source, and emitting an electromagnetic wave to the catalyst so as to form single-walled carbon nano-tubes on the catalyst. As a result, it is possible to form the nano-scale low-dimensional quantum structure on a target area.

### TECHNICAL FIELD

The present invention relates to a method for producing a nano-scale low-dimensional quantum structure and a method for producing an integrated circuit using the method for producing the structure. Particularly, the present invention relates to a method for producing carbon nanotubes and a method for producing an integrated circuit using the method for producing the carbon nanotubes.

### BACKGROUND ART

The development of high-tech materials and new materials has a significant importance as it forms the basis of industry and science and technology in a wide variety of fields such as electronics, information communications, environment energy, biotechnology, medicine, and bioscience.

In recent years, the development of nano-scale substances has drawn many interests since they possess totally novel properties and functions not found in bulk substances.

Carbon nanotubes are an example of such a nano-scale substance. It is known that the carbon nanotubes (CNTs) have a large number of special properties such as low density, high strength, high rigidity, high tractility, large surface area, high surface curvature, high thermal conductivity, specific thermal conductivity, and the like, so that the carbon nanotubes are expected to be widely used in industrial fields as a highly functional material of next generation.

Carbon nanotubes have a tube-like structure made out of a graphite sheet (graphen). There are two types of carbon nanotubes: single-walled nanotubes (SWNTs) and multi-walled nanotubes (MWNTs), depending on whether the tube is single-walled or multi-walled. The electrical properties of the carbon nanotube are unique in the sense that the nanotube can be a metal or a semiconductor depending on its chirality.

The following describes chirality of the carbon nanotube. As illustrated in FIG. 11, the chirality determines the way the graphite sheets are wound. A diameter and a chiral angle (angle of a spiral) of the carbon nanotube are unambiguously determined by the chirality. Note that, there are three types of the way the graphite sheets are wound, e.g., a zigzag type, an armchair type, and a chiral type. Such classification depends on a geometric characteristic in atoms along a circumference of the tube.

Carbon nanotubes of differing chiralities have different densities of states (electronic states). As described above, the chirality of carbon nanotubes varies, and as such a synthesis of carbon nanotubes produces structures of differing chiralities and differing electronic states.

Generally, the carbon nanotubes are synthesized by providing carbon or carbon materials at high temperature in the presence of a catalyst as required. The following describes outlines and characteristics of three methods for generating nanotubes.

(1) Ark Discharge Method

If ark discharge is carried out between carbon rods containing metal catalyst in the presence of argon or hydrogen atmosphere whose pressure is slightly lower than atmospheric pressure, about half of a steam mixture of metal and carbon is concentrated in a gas phase so as to generate soot. The rest of the steam mixture is deposited on an end of a cathode. The single-walled nanotubes are included in the soot evaporated in a gas phase and adhere to an internal wall or a cathode surface of a chamber. In this manner, the single-walled nanotubes are generated. If no catalyst is included, multi wall nanotubes are generated. According to the ark discharge method, it is possible to obtain high quality carbon nanotubes having less defects, but it is difficult to obtain a certain amount of carbon nanotubes.

(2) Laser Evaporation Method

Carbon rods containing metal catalyst are heated in an electric furnace at 1200° C., and YAG pulse laser is emitted while slowly flowing argon gas, thereby vaporizing the carbon and metal catalyst. In soot adhering to an internal wall of cold silica tube of the electric furnace, single-walled carbon nanotubes are generated. If no catalyst is included, multi-walled nanotubes are generated. The purity is relatively high, and distribution of tube diameters is narrow, but an amount of the resultant nanotubes is small.

(3) Catalyst Chemical Vapor Deposition (CCVD)

In an atmosphere of argon gas or the like in an electric furnace, gas (or liquid) containing carbon is thermally decomposed at high temperature, thereby generating single-walled nanotubes on the catalyst metal. The nanotubes can be obtained at high yield and low cost, and a large amount of nanotubes can be synthesized.

As described above, in using carbon nanotubes having various properties for industrial, manufacturing, and academic purposes, it is required to generate the carbon nanotubes in a target area (position) depending on purpose of use. Particularly, in applying the carbon nanotubes as nano-scale elements, it is desired to locally form the carbon nanotubes in a target area on the catalyst. However, none of the aforementioned methods allows formation of the carbon nanotubes in a target area. In case of adopting the CCVD, the metal catalyst is patterned on a substrate, so that it is possible to form the carbon nanotubes in the target position to some extent. However, it is impossible to form the carbon nanotubes exactly in a desired position, particularly in a local position.

Further, a conventional method for forming carbon nanotubes is not suitable for sequentially forming carbon nanotubes in desired positions on the catalyst. The following are reasons for this. That is, the first reason is such that: in the CCVD using an electric furnace or a filament, the substrate is entirely heated, so that carbon nanotubes are simultaneously formed on the entire catalyst on the substrate. Thus, in order to sequentially form carbon nanotubes in different positions, the following processes are repeatedly carried out: (1) a catalyst is patterned in a desired position; (2) carbon nanotubes are grown by the CCVD; (3) the catalyst is entirely covered with a protective film or the like, or the catalyst is chemically changed so as not to function as catalyst, or the catalyst is entirely removed from the substrate so that carbon nanotubes do not grow in the same position; (4) a catalyst is patterned in a next desired position; and (5) carbon nanotubes are gown by the CCVD. Such repetition is unfavorable in view of efficiency. The second reason is such that: In case of the CCVD carried out by electroheating, it is possible to sequentially form carbon nanotubes in target positions, but it is necessary to pattern a circuit for the electrification in advance, and it is impossible to locally heat a particular target area. Note that, it is needless to say that not only the aforementioned patterning but also patterning of the catalyst is necessary.

Further, in the present circumstances, there is no method for selectively producing carbon nanotubes having a specific state density. Also, there is no method for allowing an intended number of carbon nanotubes to cross-link.

### DISCLOSURE OF INVENTION

The present invention was made in view of the foregoing problems, and an object of the present invention is to realize a method for producing a nano-scale low-dimensional quantum structure in a target area. Further, an object of the present invention is to provide a method for selectively producing carbon nanotubes having a specific state density. Further, an object of the present invention is to provide a method for allowing an intended number of carbon nanotubes to cross-link.

In order to solve the foregoing problems, the inventors of the present invention diligently studied carbon nanotubes. As a result, they found it possible to locally form carbon nanotubes by locally emitting a laser beam onto a catalyst on a substrate, thereby completing the present invention.

In order to solve the foregoing problems, a method according to the present invention for producing a nano-scale low-dimensional quantum structure includes the steps of: bringing a catalyst which allows the nano-scale low-dimensional quantum structure to be formed thereon into contact with at least part of gas and liquid each of which contains elements constituting the nano-scale low-dimensional quantum structure; and emitting an electromagnetic wave to the catalyst so as to form the nano-scale low-dimensional quantum structure on the catalyst.

According to the arrangement, an electromagnetic wave is emitted, so that a catalyst which is positioned in an area (position) receiving the emitted electromagnetic wave and forms a nano-scale low-dimensional quantum structure thereon has higher temperature. The catalyst is in contact with gas (or liquid) containing elements constituting the nano-scale low-dimensional quantum structure. Thus, also gas (or liquid) containing elements constituting a nano-scale low-dimensional quantum structure around the catalyst has higher temperature, which results in thermal decomposition, so that a nano-scale low-dimensional quantum structure is formed on the catalyst. Thus, by controlling an electromagnetic wave, it is possible to form a nano-scale low-dimensional quantum structure in a target area.

Further, by controlling the electromagnetic wave for local emission, it is possible to locally form a nano-scale low-dimensional quantum structure in a target position on the catalyst. By utilizing this arrangement, it is possible to sequentially form nano-scale low-dimensional quantum structures in different positions. According to the arrangement, such formation can be carried out only by sequentially changing areas to which the electromagnetic wave is emitted, so that the arrangement is optimal for manufacturing application. For example, in case where the nano-scale low-dimensional quantum structure is a single-walled nanotube, the structure is highly available particularly in an integrated circuit. That is, in the integrated circuit, it is necessary to allow an intended number of single-walled carbon nanotubes having different properties (chiralities) to cross-link and grow between electrodes so as to be positioned in local areas different from each other, so that the aforementioned method can be effectively used.

Note that, as used herein, the term “nano-scale” refers to structure with a particle size or outer diameter of not more than 100 nm. The term “low-dimensional quantum structure” refers to a zero-dimensional structure (spherical shape) such as an ultrafine particle, e.g., nanoparticle and a one-dimensional structure (needle shape) such as a nanotube and a nanowire. Examples of the nano-scale low-dimensional quantum structure according to the present invention include a carbon nanotube, a carbon nanohorn, boron nitride, carbon nanofiber, carbon nanocoil, fullerene, and the like.

For a fuller understanding of the nature and advantages of the invention, reference should be made to the ensuing detailed description taken in conjunction with the accompanying drawings.

### BRIEF DESCRIPTION OF DRAWINGS

FIG. 1(a) is a schematic illustrating a CVD device for producing single-walled carbon nanotubes of one embodiment of the present invention.

FIG. 1(b) is a schematic illustrating a substrate to which a catalyst is applied.

FIG. 2 includes schematics (a), (b), and (c), (d) which are respectively illustrating single-walled carbon nanotubes formed by emitting electromagnetic waves whose wavelengths are different from each other.

FIG. 3(a) is a diagram illustrating a relation between a state density and energy of the single-walled carbon nanotubes.

FIG. 3(b) is different from FIG. 3(a), and is a diagram illustrating a relation between a state density and energy of the single-walled carbon nanotubes.

FIG. 4(a) is a schematic illustrating an electric circuit in which electrodes have not been cross-linked by the single-walled carbon nanotubes.

FIG. 4(b) is a diagram illustrating a relation between a current value and time in the electric circuit of FIG. 4(a).

FIG. 5(a) is a schematic illustrating the electric circuit in which the electrodes are cross-linked by one of the single-walled carbon nanotubes is cross-linked.

FIG. 5(b) is a diagram illustrating a relation between a current value and time in the electric circuit of FIG. 5(a).

FIG. 6(a) is a schematic illustrating the electric circuit in which the number of the single wall carbon nanotubes for cross-linking the electrodes increases.

FIG. 6(b) is a diagram illustrating a relation between a current value and time in the electric circuit illustrated in FIG. 6(a).

FIG. 7 includes: (a) which illustrates an SEM image of an Si substrate on which the single-walled carbon nanotubes are formed; and

(b) and (c) which illustrate enlarged portions of (a).

FIG. 8 includes: (a) which is different from FIG. 7 and illustrates an SEM image of another Si substrate on which single-walled carbon nanotubes are formed; and

(b) and (c) which illustrate enlarged portions of FIG. 8(a).

FIG. 9(a) is a diagram illustrating results obtained by measuring a Raman spectrum of a sample of the single-walled carbon nanotubes.

FIG. 9(b) is a diagram different from FIG. 9(a) and illustrates results obtained by measuring a Raman spectrum of a sample of the single-walled carbon nanotubes.

FIG. 10(a) is different from FIGS. 7 and 8 and illustrates an SEM image of another Si substrate on which single-walled carbon nanotubes are formed.

FIG. 10(b) illustrates enlarged portions of FIG. 10(a).

FIG. 11 is a schematic illustrating a graphite sheet so as to explain a difference in chirality of the single-walled carbon nanotubes.

FIG. 12 includes (a) and 12(b) which are schematics for illustrating a conventional production method (CCVD) of single-walled carbon nanotubes.

FIG. 13 illustrates a CVD device for producing single-walled carbon nanotubes in one embodiment of the present invention and is a schematic illustrating a CVD device which is a modification example of FIG. 1(a).

FIG. 14 is different from FIGS. 7, 8, and 11 and illustrates an SEM image of another Si substrate on which single-walled carbon nanotubes are formed.

### BEST MODE FOR CARRYING OUT THE INVENTION

### Embodiment

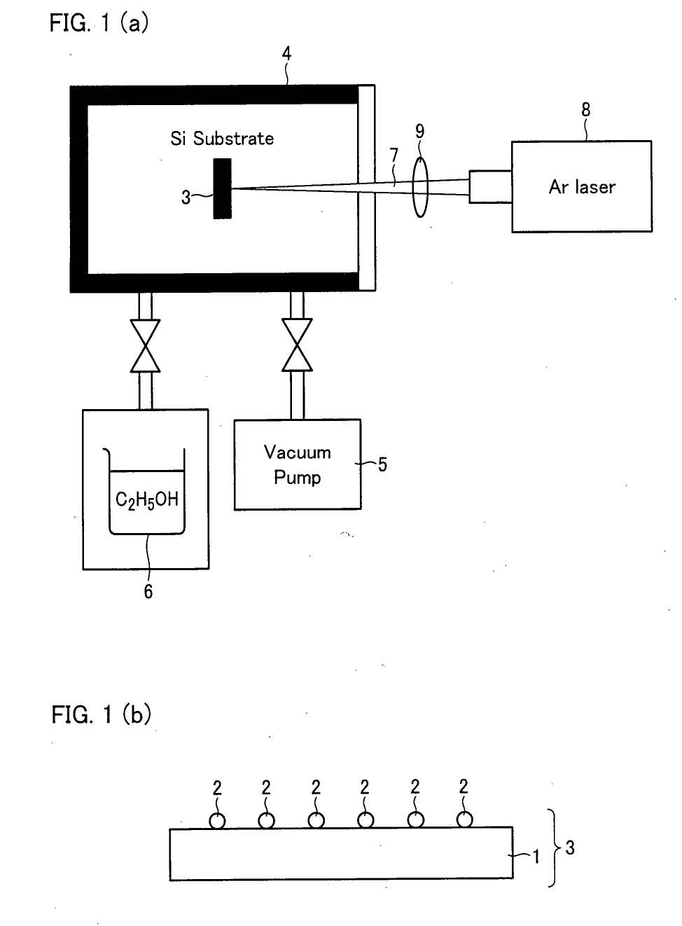

With reference to FIGS. 1 to 6, the following describes one embodiment of the present invention. Note that, the present invention is not limited to the embodiment.

Note that, in the present embodiment, single-walled carbon nanotubes are produced as a nano-scale low dimensional quantum structure. However, a product which can be produced in accordance with the present invention is not limited to the single-walled carbon nanotubes. Examples of the product include multi-walled carbon nanotubes, carbon nanohorn, boron nitride, carbon nanofiber, carbon nanocoil, fullerene, and the like.

The production method of the single-walled carbon nanotubes is as follows. First, as illustrated in FIG. 1(b), a catalyst 2 for forming single-walled carbon nanotubes are applied to a substrate 1.

Any material may be used for the substrate 1 as long as the material can resist high temperature caused by emission of an electromagnetic wave. Examples of the material include silicon, zeolite, quartz, sapphire, and the like.

Further, an example of the catalyst 2 used herein is a catalyst made of metal or metal oxide. For example, it is possible to use iron, nickel, cobalt, platinum, palladium, rhodium, lanthanum, yttrium, and the like. Further, the catalyst 2 may be obtained by mixing metal and metal oxide with each other. An example thereof is a mixture of iron (Fe), molybdenum (Mo), and aluminum oxide (Al₂O₃). Iron is referred to also as catalyst metal, becomes fine particles, and serves as a base on which carbon nanotubes grow. Molybdenum is referred to also as support metal, and promotes action of the catalyst metal (iron). Aluminum oxide assists the catalyst metal in becoming fine particles. By appropriately setting a mixture ratio of iron (Fe), molybdenum (Mo), and aluminum oxide (Al₂O₃), it is possible to efficiently form carbon nanotubes. However, even if the mixture ratio is changed, single-walled carbon nanotubes are formed with a difference in efficiency, so that it is not necessary to particularly limit the mixture ratio.

Further, it is preferable that a particle size of the catalyst is several nm at temperature at which carbon nanotubes grow.

The catalyst 2 is applied to the substrate 1 in accordance with a conventional method. For example, the catalyst 2 is mixed with methanol, and a resultant is dropped onto the substrate 1.

Next, as illustrated in FIG. 1(a), a sample 3 constituted of the substrate 1 to which the catalyst 2 has been applied is disposed in a center of a chamber 4. The chamber 4 may be arranged in any manner as long as an inside thereof is vacuumed and a carbon source 6 is supplied therein. Further, the chamber 4 includes a window (optical window) which allows an electromagnetic wave 7 to be directed into the chamber 4, or the chamber 4 allows the window to be installed thereon. As a material of the window, it is possible to use a glass plate, an acryl plate having high transmissivity, a quarts, and the like, but the material is not limited to them.

Examples of the carbon source include acetylene, benzene, ethane, ethylene, ethanol, and the like.

The inside of the chamber 4 is vacuumed with a vacuum pump 5, and the carbon source 6 is flown so as to be vaporized. Note that, the inside of the chamber is vacuumed in order to remove air from the chamber to some extent and in order to vaporize ethanol. Note that, if gas which has no influence onto formation of carbon nanotubes is allowed to exist instead of air and ethanol is vaporized through bubbling, it is not necessary to vacuum the inside of the chamber. Further, examples of the gas used instead of air include inert gas such as helium, neon, argon, and the like. That is, the chamber 4 may be arranged in any manner as long as the following two conditions are satisfied: (1) there is no gas which prevents growth of carbon nanotubes; and (2) gas or liquid serving as the carbon source can be in contact with the catalyst.

Further, as illustrated in FIG. 1(a), the electromagnetic wave 7 is emitted to the sample 3. The electromagnetic wave 7 to be emitted is not particularly limited. An example thereof is a laser beam. If the laser beam is used, it is easier to adjust a wavelength and strength of the electromagnetic wave to be emitted. Therefore, it is possible to efficiently emit a high energy electromagnetic wave to a mixture of nano-scale low-dimensional quantum structures. Further, the laser beam has high linearity and hardly spreads, so that the laser beam can be easily converged. By converging the laser beam, it is possible to locally emit the electromagnetic wave. Thus, by using the laser beam, it is possible to easily form single-walled carbon nanotubes in a target area.

Favorable examples of a light source 8 include Ar laser, CO₂ laser, YAG laser, and the like. Further, laser intensity may be set to be any value as long as single-walled carbon nanotubes are formed on the sample 3. Further, it is preferable that emission time is several seconds or more. For example, the emission time may be one minute.

Further, in order to converge the electromagnetic wave 7 to be emitted, an optical member such as a condenser lens 9 or the like may be used. However, the light convergence is not limited to this. Further, the optical member is not particularly limited as long as the optical member converges the electromagnetic wave 7 so that temperature of an emission spot allows formation of the single-walled carbon nanotubes. Note that, in the present specification, the “emission spot” refers to a range in which any variation caused by the emission of the electromagnetic wave 7 with respect to the sample 3 (or the substrate 1) can be visually recognized in SEM observation.

As described above, the electromagnetic wave 7 is emitted, so that part of the catalyst 2 on the substrate 1 which part corresponds to an area (position) receiving the electromagnetic wave 7 has higher temperature. The catalyst 2 is in contact with gas (or liquid) serving as the carbon source 6. Thus, also temperature of the gas (or liquid) serving as the carbon source 6 rises, which results in thermal decomposition, so that the single-walled carbon nanotubes are formed on the catalyst 2 on the substrate 1. As a result, by controlling the electromagnetic wave, it is possible to form the single-walled carbon nanotubes on the catalyst 2 on the substrate 1. Note that, it is possible to carry out all the production steps at room temperature.

The formation of the single-walled carbon nanotubes can be confirmed by measuring Raman scattering light for example. Further, the confirmation is carried out by observing a SEM (Scanning Electron Microscope) image.

Further, in the method according to the present embodiment for producing single-walled carbon nanotubes, single-walled carbon nanotubes having a state density which resonates with a wavelength of the electromagnetic wave 7 may be selectively formed on the catalyst.

This is based on the following reason. The single-walled carbon nanotubes which resonate with the emitted electromagnetic wave 7 more greatly absorb the electromagnetic wave 7, so that only the single-walled carbon nanotubes which resonate with the electromagnetic wave 7 are formed, or formation thereof is promoted. Therefore, the single-walled carbon nanotubes which resonate with the wavelength of the electromagnetic wave 7 can be selectively or preferentially formed on the catalyst 2 of the sample 3.

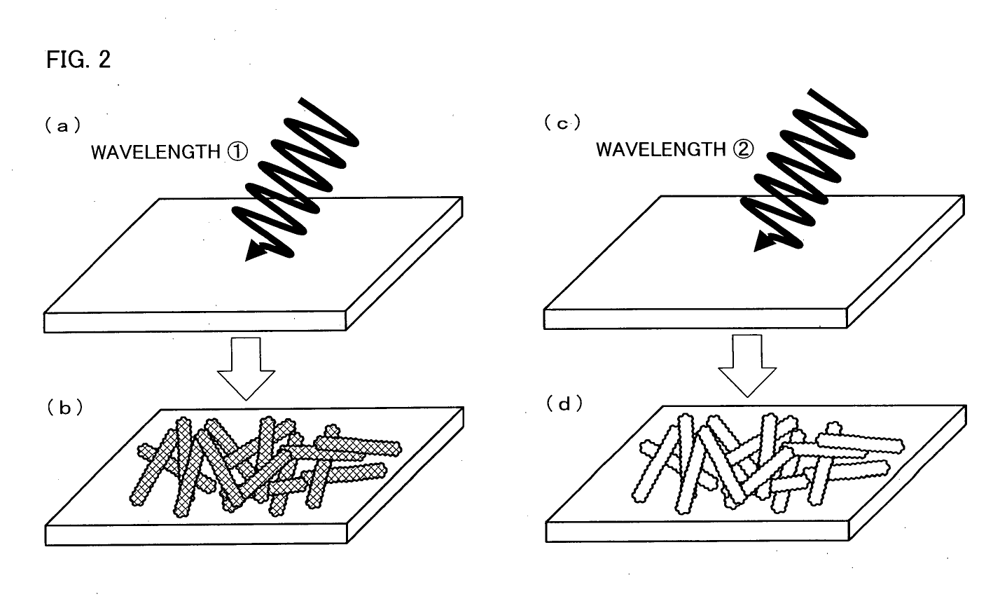

That is, as illustrated in FIGS. 2(a) and 2(b) and FIGS. 2(c) and 2(d), the single-walled carbon nanotubes having different state densities are formed due to the wavelength of the electromagnetic wave.

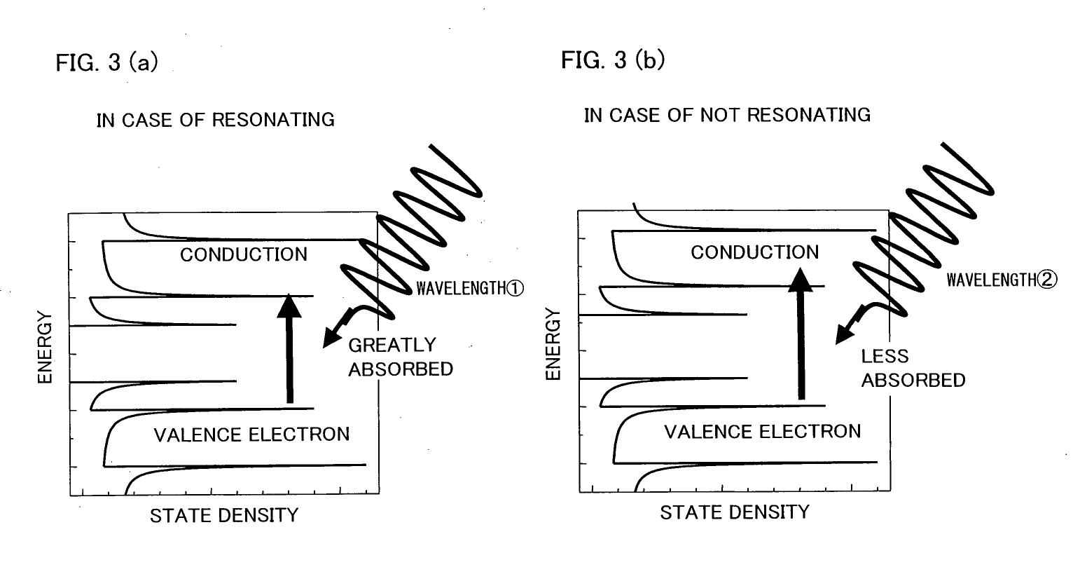

The resonance is explained as follows. The state densities of the single-walled carbon nanotubes having different chiralities are different from each other. Thus, as illustrated in FIG. 3, in case of emitting an electromagnetic wave having a certain wavelength onto single-walled carbon nanotubes having a certain state density, resonance occurs when energy difference on the spike is in proximity in electromagnetic wave energy. This results in greater absorption of the electromagnetic wave. Note that, when the chirality varies, the energy difference on the spike varies in the state density.

Note that, in order to confirm the formation of the single-walled carbon nanotubes which resonate with the emitted electromagnetic wave, a spectrum of the single-walled carbon nanotubes is measured by using Raman spectrometry for example. By measuring Raman spectra having various wavelengths and confirming appearance and a position of a peak of each spectrum, it is possible to confirm formation of the single-walled carbon nanotubes which resonate with the emitted electromagnetic wave. In this case, it is necessary to measure the spectrum by using an electromagnetic wave having a low energy density so as to prevent deformation and breakage of the single-walled carbon nanotubes. Note that, how to confirm the formation of the single-walled carbon nanotubes is not limited to the foregoing method.

Note that, in the foregoing explanation, the electromagnetic wave is emitted after flowing the carbon source, but the following method may be adopted. That is, the catalyst is prepared on the substrate, and the resultant is placed in the vacuumed chamber, and the chamber is further vacuumed with a pump (the same operation as the aforementioned process so far), and the carbon source is flown after emitting the electromagnetic wave, thereby forming the single-walled carbon nanotubes. In view of the conventional CVD, this order is more general, and carbon nanotubes having higher purity may be formed.

Further, the following method may be adopted. That is, the catalyst is prepared on the substrate, the resultant is placed in the vacuumed chamber, and the chamber is further vacuumed with a pump (the same operation as the aforementioned process so far), and the substrate is heated to some extent and then an electromagnetic wave is emitted. It is possible to form the carbon nanotubes also by flowing ethanol, and there is a high possibility that the chirality may be controllable. Note that, in heating the substrate, it is possible to adopt an electric furnace, a filament, electroheating, and the like. The heating temperature is preferably a temperature at which the single-walled carbon nanotubes grow or a lower temperature.

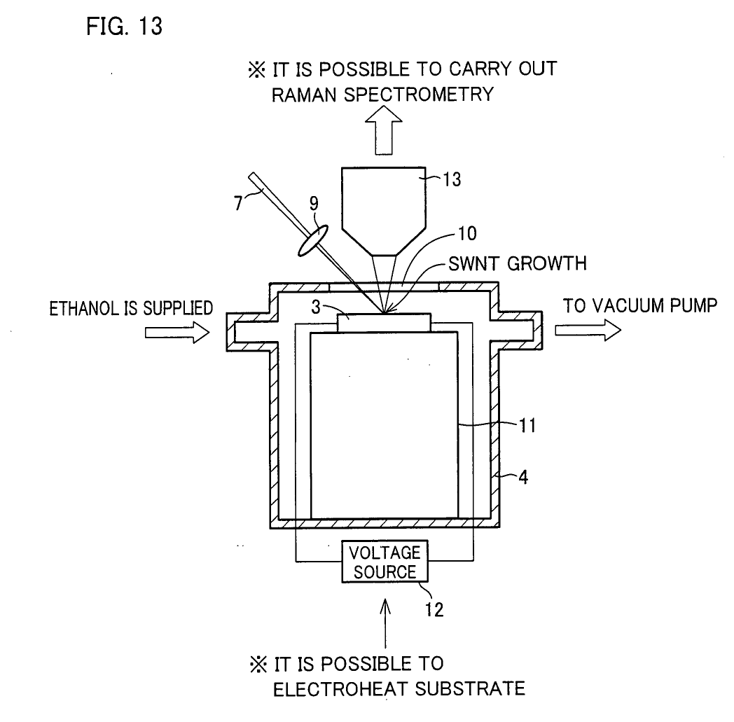

As a device for heating the substrate and emitting the electromagnetic wave, it is possible to use a CVD device illustrated in FIG. 13. The CVD device is a modification example of the CVD device illustrated in FIG. 1(a) and includes a power source 12 for heating the substrate 1 to which the catalyst 2 has been applied. Further, as illustrated in FIG. 13, the CVD device may include an optical microscope 13 by which a position receiving the laser beam can be confirmed, a spot size can be adjusted, and Raman spectroscopic measurement can be performed. Through the optical window 10 made of quarts, the electromagnetic wave 7 narrowed by a condenser lens 9 whose focal distance is nearer is directed to the sample 3 constituted of the substrate 1 to which the catalyst 2 has been applied. An angle at which the electromagnetic wave 7 is emitted (emission angle) is not particularly limited as long as the electromagnetic wave 7 is entirely reflected by the optical window 10. However, as the emission angle is further away from an angle perpendicular to the substrate 1 to which the catalyst 2 has been applied, refraction by the optical window deforms the spot into an oval shape. As a result, the electromagnetic wave is emitted to a wider area, so that the intensity is less dense. Thus, in order to emit the electromagnetic wave “locally to a circular area with high density of intensity (with high efficiency)”, it is preferable to perpendicularly emit laser.

In the CVD device illustrated in FIG. 13, an objective lens of the optical microscope 13 is a barrier. Thus, the electromagnetic wave 7 is emitted from a direction oblique with respect to the substrate 1 to which the catalyst 2 has been applied. Alternatively, the electromagnetic wave 7 may be emitted from a direction perpendicular to the substrate 1 to which the catalyst 2 has been applied by using the objective lens of the optical microscope 13 as a condenser lens.

Further, a sample placement table 11 is disposed in the vacuumed chamber 4 so that the sample 3 constituted of the substrate 1 to which the catalyst 2 has been applied is placed on the sample placement table 11.

In the device illustrated in FIG. 13, for example, an Ar laser whose wavelength is 514.5 nm and laser intensity is 100 mW or an He—Cd laser whose wavelength is 325 nm and laser intensity is 60 mW is used as the electromagnetic wave 7, so that it is possible to form carbon nanotubes in short time such as 0.2 seconds.

It is possible to grow the single-walled carbon nanotubes due to the heat caused by emission carried out in extremely short time, so that it is possible to greatly suppress damage of the substrate or damage of devices such as electrodes and the like that are provided on the substrate. Thus, this method has not only such advantage that heat caused by the electromagnetic wave exerts no damage to portions other than the portion receiving the electromagnetic wave but also such advantage that damage exerted to the portion receiving the electromagnetic wave (damage exerted to an area on which the single-walled carbon nanotubes are formed) is extremely small.

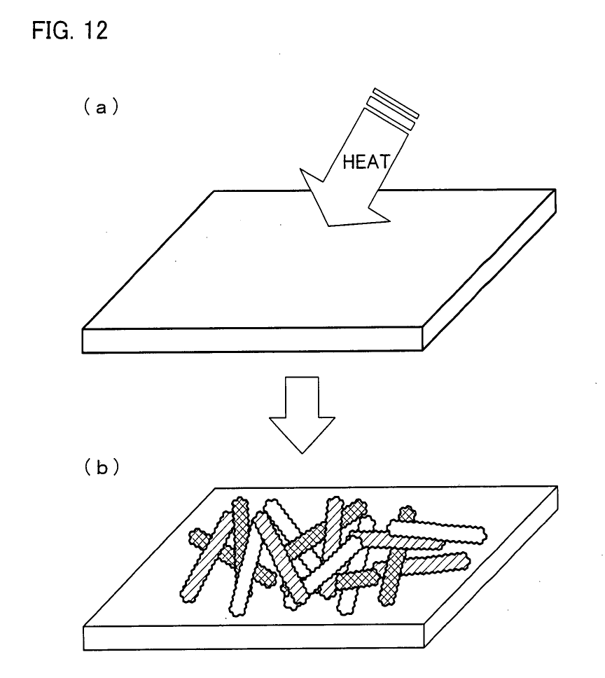

Note that, according to the conventional CVD, as illustrated in FIG. 12, thermal decomposition carried out at high temperature allows formation of the single-walled carbon nanotubes which have various state densities, that is, the single-walled carbon nanotubes which have chiralities different from each other.

Further, the method according to the present embodiment for producing the single-walled carbon nanotubes may be arranged so that: the electromagnetic wave 7 is emitted so as to control the number of single-walled carbon nanotubes cross-linking the electrodes.

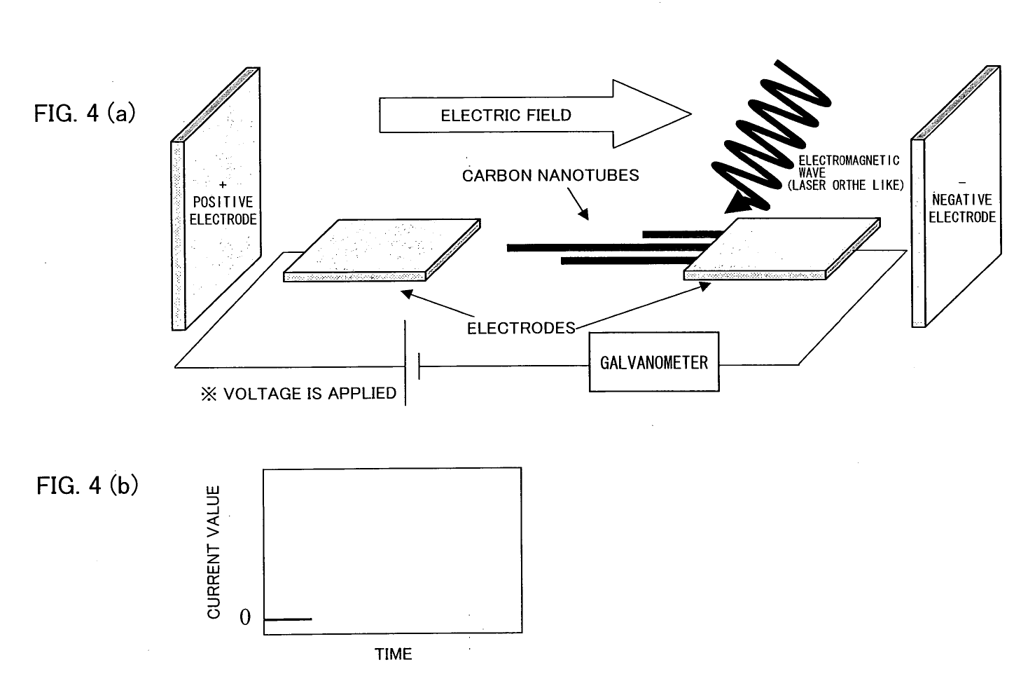

For example, suppose the case of using the single-walled carbon nanotubes so as to cross-link the electrodes. As illustrated in FIG. 4, when the electromagnetic wave is emitted to one of the electrodes which has the catalyst thereon and is in contact with the carbon source, the single-walled carbon nanotubes are formed. Before the electrodes are not cross-linked by the single-walled carbon nanotubes, no current flows as illustrated in FIG. 4.

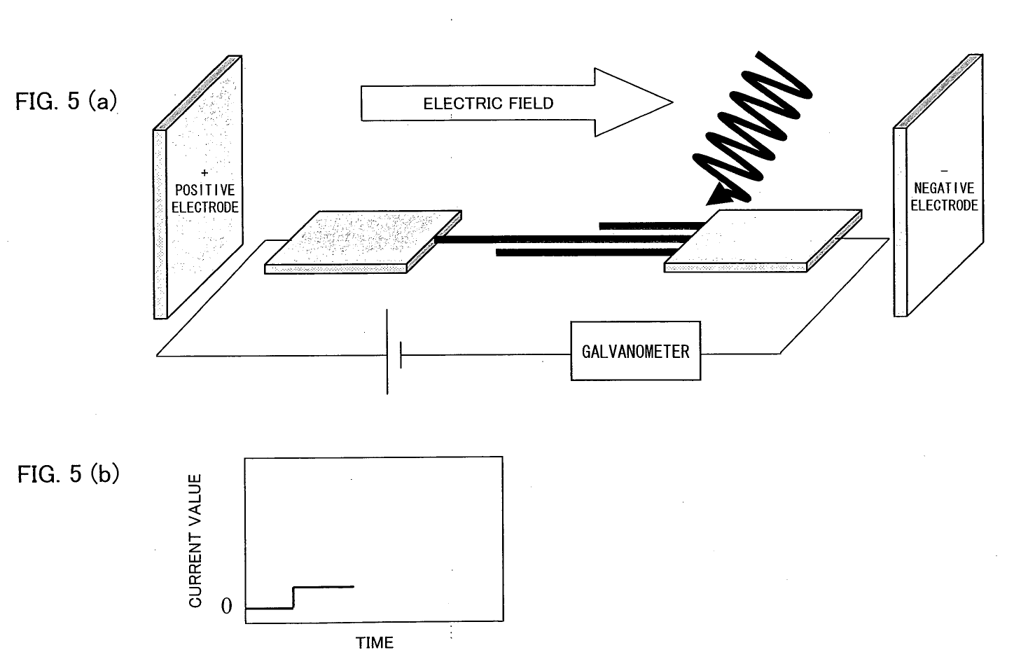

Further, as illustrated in FIG. 5, the electromagnetic wave is emitted, so that the single-walled carbon nanotubes grow. When the electrodes are cross-linked by one carbon nanotube, a certain current corresponding thereto flows.

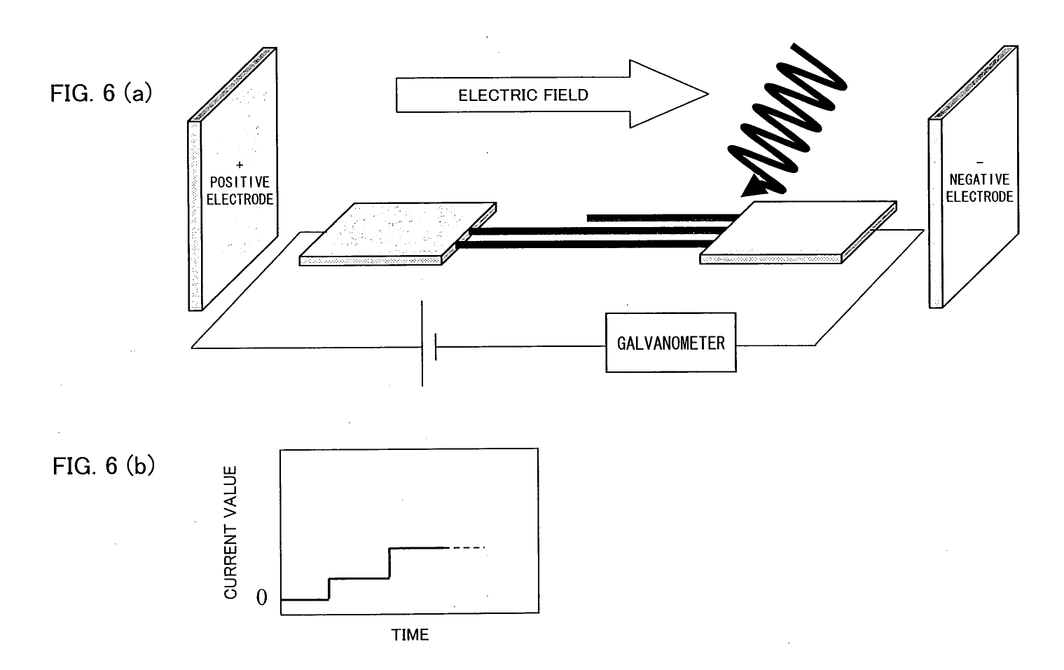

Further, as illustrated in FIG. 6, when an intended number of single-walled carbon nanotubes reach the other electrode, emission of the electromagnetic is stopped. As a result, it is possible to control the number of single-walled carbon nanotubes which cross-link the electrodes. Note that, a direction in which the single-walled carbon nanotubes for cross-linking the electrodes grow is controlled by horizontally applying am electric field between the electrodes. As described above, it is possible to confirm that an intended number of single-walled carbon nanotubes cross-link the electrodes by measuring current flowing between the electrodes. That is, as the number of single-walled carbon nanotubes cross-linking the electrodes increases, the current value gradually increases. By observing this condition, it is possible to carry out the foregoing confirmation. In this case, unlike the conventional CVD, the arrangement is almost free from such a problem that waste heat causes formation of single-walled carbon-nanotubes, so that the method according to the present embodiment for producing single-walled carbon nanotubes is optimal in controlling the number of carbon nanotubes which cross-link the electrodes.

In this manner, according to the method of the present embodiment for producing single-walled carbon nanotubes, it is possible to form the single-walled carbon nanotubes in an extremely small target area, so that the single-walled carbon nanotubes can be used as a nano-scale element in an integrated circuit. In this manner, the single-walled carbon nanotubes can be optically applied also to an extremely small electric circuit such as an integrated circuit.

Note that, usage of the method for producing the single-walled carbon nanotubes so that the number thereof is controlled is not limited to the integrated circuit. According to the method of the present embodiment, it is possible to allow an intended number of single-walled carbon nanotubes to cross-link the electrodes. That is, it is possible to raise temperature of only the target area by emitting the electromagnetic wave, so that the arrangement is almost free from such a problem that waste heat causes formation of single-walled carbon nanotubes. Thus, it is possible to grow the single-walled carbon nanotubes while controlling the number of single-walled carbon nanotubes which cross-link the electrodes.

### EXAMPLE

Example of the present invention is detailed as follows with reference to Experiments 1 to 6. However, the present invention is not limited to the Example. Note that, all the experiments were carried out at room temperature.

[Experiment 1] Formation of Substrate

A catalyst containing iron (Fe), molybdenum (Mo), and aluminum oxide (Al₂O₃) was applied to an Si substrate. Here, a catalyst of iron (Fe), a catalyst of molybdenum (Mo), and a catalyst of aluminum oxide (Al₂O₃) were mixed with one another by using methanol, and the mixture was dropped onto the substrate, thereby applying the mixed catalysts to the substrate.

Note that, in the present example, the catalysts were mixed as follows by using the following chemicals.

Chemical A: Iron (III) nitrate nonahydrate 98% (iron-containing solid)

Fe(No₃)₃.9H₂O (product of Aldrich Company)

Chemical B: Bis(acetylacetonato)-dioxomolybdenum (IV)

(molybdenum-containing solid)

(C₅H₈O₂)₂MoO₂ (product of Aldrich Company)

Chemical C: Aluminum oxide (aluminum oxide solid)

“Fumed Alumina” Al₂O₃ (product of Degussa Company)

First, 40 mg of the chemical A, 3 mg of the chemical B, and 30 mg of the chemical C were placed in a beaker, and 30 ml of methanol was added thereto, and they were slightly mixed with one another. Next, the resultant was subjected to ultrasonic cleaning with an ultrasonic cleaner for not more than 30 minutes so as to prepare suspensoid of catalysts. In this manner, preparation of the catalyst was completed.

Further, a sample constituted of an Si substrate to which the catalyst was applied was placed in a chamber, and ethanol (gas) was flown in the chamber having been vacuumed, thereby vaporizing ethanol.

[Experiment 2] Laser Emission (180 mW)

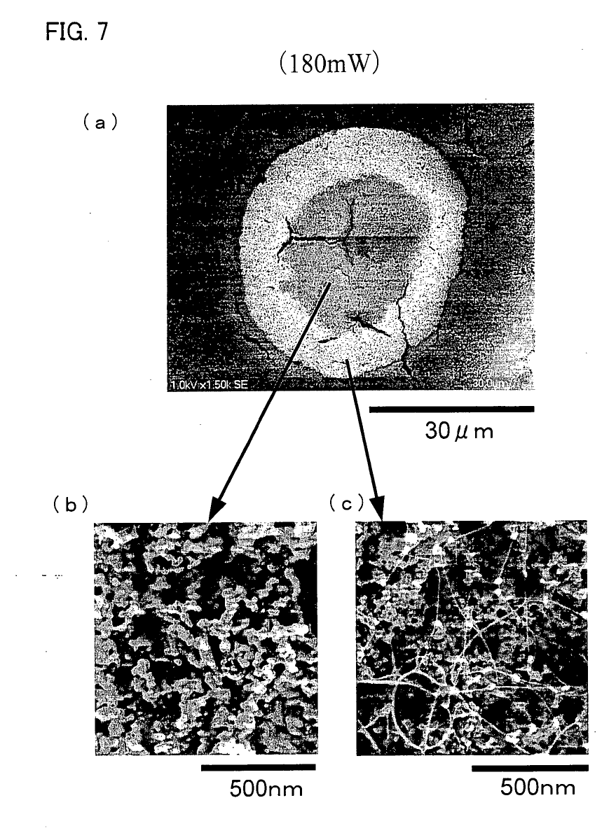

In a CVD device illustrated in FIG. 1(a), with a condenser lens (focal distance was 10 cm: product of SIGMA KOKI), an Ar laser whose wavelength was 514.5 nm and laser intensity was 180 mW was emitted, for about one minute, to the catalyst on the Si substrate which had been prepared in Experiment 1. Each of FIGS. 7(a) to 7(c) is an SEM image at a laser spot on the Si substrate. Note that, as described in the present example, the laser spot refers to a range in which any variation caused by the emission of the laser with respect to the Si substrate having the catalyst thereon can be visually recognized in SEM observation. In this case, as illustrated in FIG. 7(a), the laser spot was observed in a range whose diameter was 40 μm. In a central portion of the laser spot shown in FIG. 7(b), no single-walled carbon nanotubes were observed. This may be because catalyst metal fine particles were not formed due to high laser intensity. Further, as illustrated in FIG. 7(c), the single-walled carbon nanotubes were formed around the laser spot. This shows that: due to temperature distribution in the laser spot, temperature of the peripheral portion of the laser spot corresponded to temperature at which the catalyst metal fine particles were formed and temperature at which the single-walled carbon nanotubes were grown.

[Experiment 3] Laser Emission (160 mW)

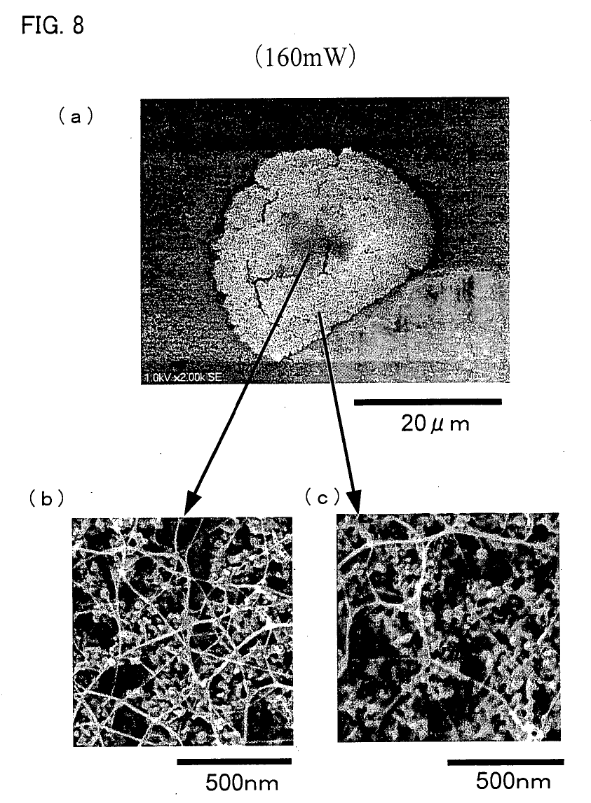

In the CVD device illustrated in FIG. 1(a), with a condenser lens (focal distance was 10 cm: product of SIGMA KOKI), an Ar laser whose wavelength was 514.5 nm and laser intensity was 160 mW was emitted, for about one minute, to the catalyst on the Si substrate which had been prepared in Experiment 1. Each of FIGS. 8(a) to 8(c) is an SEM image at a laser spot on the Si substrate. In this case, as illustrated in FIG. 8(a), the laser spot was observed in a range whose diameter was 30 μm. Also in a central portion of the laser spot shown in FIG. 8(b) and also in the peripheral portion of the laser spot illustrated in FIG. 8(c), single-walled carbon nanotubes were formed. This shows that: the laser intensity was appropriate, and the emission of the laser caused the whole laser spot to have temperature at which the catalyst metal fine particles were formed and temperature at which the single-walled carbon nanotubes were grown.

[Experiment 4] Raman Spectroscopic Measurement

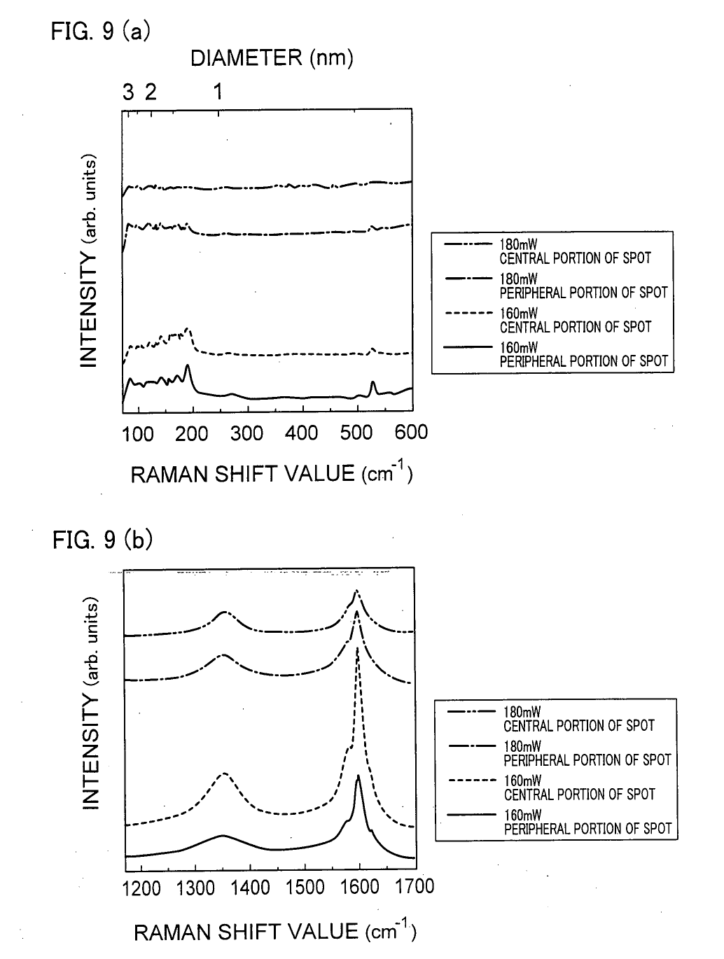

A Raman spectrum of a sample on which the single-walled carbon nanotubes prepared in Experiments 2 and 3 had been formed was observed. Each of FIGS. 9(a) and 9(b) shows the measurement results. An Ar laser (wavelength was 514.5 nm and laser intensity was 15 mW) was used as an excitation light source. As apparent from FIGS. 9(a) and 9(b), when the laser beam of Experiment 2 whose laser intensity was 180 mW was emitted, a spectrum caused by the single-walled carbon nanotubes was observed in the peripheral portion of the laser spot. Further, when the laser beam of Experiment 3 whose laser intensity was 160 mW was emitted, a spectrum caused by the single-walled carbon nanotubes was observed in the whole laser spot. These results were identical with the results of the SEM observations in Experiments 2 and 3.

[Experiment 5]

In the CVD device illustrated in FIG. 1(a), with a condenser lens (focal distance was 7 cm: product of SIGMA KOKI), an Ar laser whose wavelength was 514.5 nm and laser intensity was lower than that of Experiment 3 was emitted, for about one minute, to the catalyst on the Si substrate which had been prepared in Experiment 1.

In Experiments 2 and 3, a glass plate was used as the chamber window. However, in Experiment 5, an acryl plate having high transmissivity was used instead of the glass plate. Further, in Experiments 2 and 3, the laser beam was converged through the condenser lens without any modification. On the other hand, in Experiment 5, the laser beam was converged after being spread in parallel by using a special lens, thereby realizing more exact convergence. Further, in order to solve such a problem that a wavelength other than 514.5 nm was slightly contained, a plasma line filter was used so as to remove the wavelength other than 514.5 nm. Experiment 5 had these three differences except for the condenser lens.

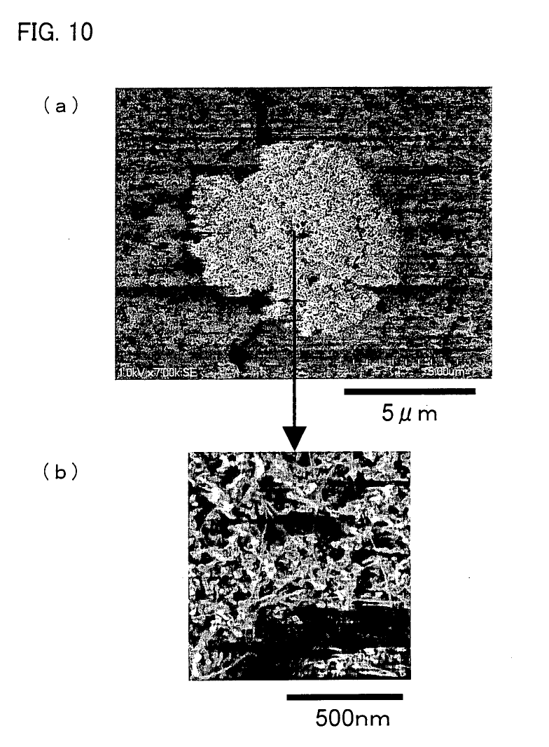

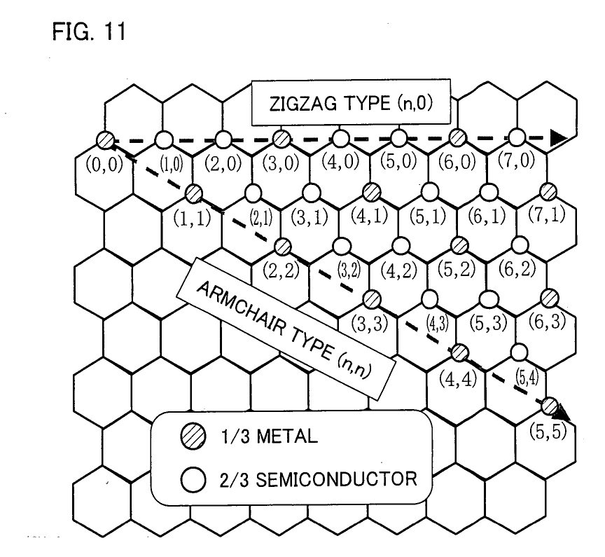

Each of FIGS. 10(a) and 10(b) illustrates an SEM image at a laser spot on an Si substrate of Experiment 5. In this case, as illustrated in FIG. 10(a), the laser spot was observed in a local range whose diameter was 5 μm. As illustrated in FIG. 10(b), single-walled carbon nanotubes were formed on the whole laser spot. A device problem and an optical system were improved in this manner, so that the single-walled carbon nanotubes were formed in the local range whose diameter was 5 μm.

[Experiment 6]

In Experiment 6, a CVD device illustrated in FIG. 13 was used. an Ar laser whose wavelength was 514.5 nm and laser intensity was 100 mW was emitted, for about 0.2 seconds, to the catalyst on the Si substrate prepared in Experiment 1.

Note that, in Experiment 6, a condenser lens (focal distance was about 3 cm) was used. Quarts was used as the chamber window. Further, a laser beam was emitted not perpendicularly but obliquely (about 45°) with respect to the sample. Experiment 6 was different from Experiments 2, 3, and 5 in this point. Note that, in the present experiment, the CVD device illustrated in FIG. 13 was used, but the Si substrate was not heated.

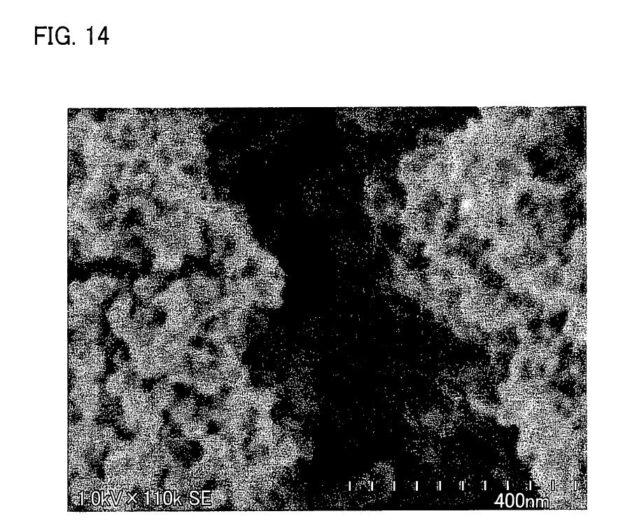

FIG. 14 is an SEM image of a central portion of a laser spot on the Si substrate in case of using the Ar laser in Experiment 6. As apparent from observation of the central portion shown in FIG. 14, it was confirmed that several single-walled carbon nanotubes were formed on the central portion of the laser spot.

Further, Raman spectroscopic measurement was carried out with respect to the Si substrate in case of using an He—Cd laser. As a result, it was confirmed that the single-walled carbon nanotubes were formed (not shown).

The experiment results show that: it is possible to form the single-walled carbon nanotubes in a target area by emission of a laser beam. Further, it was found that it is possible to form the single-walled carbon nanotubes in a local area on the substrate by converging the laser beam and locally emitting the laser beam.

As described above, in order to solve the foregoing problems, a method according to the present invention for producing a low dimensional quantum structure includes the steps of: bringing a catalyst which allows the nano-scale low-dimensional quantum structure to be formed thereon into contact with at least part of gas and liquid each of which contains elements constituting the nano-scale low-dimensional quantum structure; and emitting an electromagnetic wave to the catalyst so as to form the nano-scale low-dimensional quantum structure on the catalyst.

Further, the method according to the present invention for producing a nano-scale low-dimensional quantum structure may be arranged so that the electromagnetic wave is locally emitted to a substrate, to which the catalyst has been applied, so as to form the nano-scale low-dimensional quantum structure on the catalyst so that the nano-scale low-dimensional quantum structure is positioned in a target area of the substrate.

According to the method, it is possible to form the nano-scale low-dimensional quantum structure on a local area. The electromagnetic wave is locally emitted, which results in local heating. Thus, a portion other than the area receiving the electromagnetic wave is free from any thermal influence. The term “thermal influence” refers to damage exerted to elements such as other electrode and an insulating film in case where the elements are provided on the substrate for example, or refers to influence exerted to growth of a catalyst on other area of the substrate into carbon nanotubes for example. Further, it is possible to grow the carbon nanotubes with heat caused by emission carried out in extremely short time, so that it is possible to greatly suppress thermal influence exerted to the area receiving the electromagnetic wave or thermal influence exerted to a portion around the area receiving the electromagnetic wave, particularly, it is possible to greatly suppress damage.

Note that, the substrate may be made of any material as long as the material can resist high temperature. Examples thereof include silicon (Si), zeolite, quarts, sapphire, and the like.

Further, the method according to the present invention for producing a nano-scale low-dimensional quantum structure may be arranged so that the electromagnetic wave is emitted to a substrate, on which the catalyst has been patterned in accordance with lithography, so as to form the nano-scale low-dimensional quantum structure on the catalyst so that the nano-scale low-dimensional quantum structure is positioned in a target area of the substrate.

According to the method, the electromagnetic wave is emitted to an entire face of the area in which the catalyst has been patterned, so that it is possible to form the nano-scale low dimensional quantum structure on the patterned area.

Further, the method according to the present invention for producing a nano-scale low-dimensional quantum structure may be arranged so that the nano-scale low-dimensional quantum structure is capable of being formed at a room temperature.

According to the method, it is possible to safely and easily produce the low-dimensional quantum structure at room temperature without setting temperature in the chamber (reaction chamber) high. According to the method, it is possible to raise temperature of the catalyst with heat obtained by converging the electromagnetic wave, so that it is not necessary to adopt electroheating such as an electric furnace, a hot filament, and the like. Thus, a device for forming the nano-scale low-dimensional quantum structure is much simpler than conventional arts, so that it is possible to produce the nano-scale low-dimensional quantum structure without increasing the cost.

Further, according to the method according to the present invention for producing the nano-scale low-dimensional quantum structure, when each of the gas and the liquid is a carbon hydride, carbon nanotubes can be formed as the nano-scale low-dimensional quantum structure.

A structure and functions of the carbon nanotubes have been clarified. Thus, according to the foregoing method, it is possible to form the carbon nanotubes in a target area, so that the method is directly applicable to industrial or academic purpose.

Further, the method according to the present invention for producing a nano-scale low-dimensional quantum structure may be arranged so that the catalyst is made of metal or metal oxide. Further, the method may be arranged so that the catalyst is a mixed catalyst obtained by mixing iron, molybdenum, and aluminum oxide.

Further, the method according to the present invention for producing a nano-scale low-dimensional quantum structure may be arranged so that a nano-scale low-dimensional quantum structure having a state density which resonates with a wavelength of the electromagnetic wave is selectively formed on the catalyst.

The electromagnetic wave is emitted, so that the nano-scale low-dimensional quantum structure which resonates with the emitted electromagnetic wave more greatly absorbs the electromagnetic wave. As a result, only the nano-scale low-dimensional quantum structure is formed, or growth of only the nano-scale low-dimensional quantum structure is promoted. Therefore, the nano-scale low-dimensional quantum structure having a state density which resonates with a wavelength of the electromagnetic wave can be selectively formed on the catalyst or preferentially formed.

Further, the method according to the present invention for producing a nano-scale low-dimensional quantum structure may be arranged so as to include the steps of: disposing a pair of electrodes, at least one of which contains a catalyst, in an electric field; emitting an electromagnetic wave to the electrode containing the catalyst so as to grow the nano-scale low-dimensional quantum structure between the electrodes; measuring an electric property between the electrodes; and controlling electromagnetic wave emission time in accordance with a value obtained by measuring the electric property, wherein the nano-scale low-dimensional quantum structure is grown while controlling the number of carbon nanotubes which cross-link the electrodes.

According to the method, it is possible to allow an intended number of nano-scale low-dimensional quantum structures to cross-link the electrodes. That is, it is possible to cause only the target area to have high temperature by emitting the electromagnetic wave, so that this arrangement is almost free from such a problem that waste heat causes formation of a nano-scale low-dimensional quantum structure. Thus, it is possible to grow single-walled carbon nanotubes while controlling the number of the single-walled carbon nanotubes which cross-link the electrodes.

For example, suppose the case of using the single-walled carbon nanotubes as a nano-scale low-dimensional quantum structure for cross-linking two electrodes. The electromagnetic wave is emitted to the electrode to which the catalyst has been applied, and the emission of the electromagnetic wave is stopped when an intended number of single-walled carbon nanotubes reach the other electrode. This allows the number of single-walled carbon nanotubes which cross-link the electrodes to be intentionally set. Note that, a direction in which the single-walled carbon nanotubes which cross-link the electrodes grow is controlled by horizontally applying an electric field between the electrodes. Further, it is possible to confirm that an intended number of single-walled carbon nanotubes cross-link the electrodes for example by measuring a current flowing between the electrodes. That is, as the number of single-walled carbon nanotubes which cross-link the electrodes increases, a current value gradually increases. By observing this condition, it is possible to carry out the confirmation. In this case, unlike the conventional CVD, the arrangement is almost free from such a problem that waste heat causes formation of single-walled carbon nanotubes, so that the method is optimal in controlling the number of single-walled carbon nanotubes which cross-link the electrodes.

Further, the method according to the present invention for producing a nano-scale low-dimensional quantum structure may be arranged so that a laser beam is used as the electromagnetic wave.

By using the electromagnetic wave as the laser beam, it is possible to make it easier to adjust a wavelength and intensity of the emitted electromagnetic wave. Therefore, it is possible to efficiently emit a high energy electromagnetic wave to a mixture of nano-scale low-dimensional quantum structures. Further, the laser beam has high linearity and hardly spreads, so that it is easy to converge the laser beam. The convergence allows the electromagnetic wave to be locally emitted. Thus, by using the laser beam, it is possible to easily form the nano-scale low-dimensional quantum structure in a target area. Examples of a light source of the laser beam include Ar laser and He—Cd laser.

In order to solve the foregoing problems, a method according to the present invention for producing an integrated circuit includes any one of the aforementioned methods as a production step, wherein the catalyst which allows the nano-scale low-dimensional quantum structure to be formed thereon is brought into contact with at least one of the gas and the liquid each of which contains the element constituting the nano-scale low-dimensional quantum structure, and the electromagnetic wave is locally emitted to an electrode, to which the catalyst has been applied, so as to form the nano-scale low-dimensional quantum structure on the catalyst so that the nano-scale low-dimensional quantum structure is positioned on a target area of the electrode, and the nano-scale low-dimensional quantum structure cross-links the electrodes of the integrated circuit.

According to the method, it is possible to form the nano-scale low-dimensional quantum structures in an extremely small target area, so that the nano-scale low-dimensional quantum structure can be used as a nano-scale element in an integrated circuit. Further, the electromagnetic wave is locally emitted, which results in local heating. Thus, a portion other than the area receiving the electromagnetic wave is free from any thermal influence in producing the integrated circuit. The term “thermal influence” refers to damage exerted to elements such as other electrode and an insulating film in case where the elements are provided on the substrate for example, or refers to influence exerted to growth of a catalyst on other area of the substrate into carbon nanotubes for example. Further, it is possible to grow the carbon nanotubes with heat caused by emission carried out in extremely short time, so that it is possible to greatly suppress thermal influence exerted to the area receiving the electromagnetic wave or thermal influence exerted to a portion around the area receiving the electromagnetic wave, particularly, it is possible to greatly suppress damage.

Further, the method according to the present invention for producing an integrated circuit may be arranged so that the nano-scale low-dimensional quantum structure is a carbon nanotube and is used as a material for cross-linking the electrodes. In case of using the nano-scale low-dimensional quantum structure as the material for cross-linking the electrodes, it is possible to form nano-scale low-dimensional quantum structures while controlling the number of the nano-scale low-dimensional quantum structures which cross-link the electrodes. Thus, the method is optimally applicable to an extremely small electric circuit such as an integrated circuit.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

### INDUSTRIAL APPLICABILITY

As described above, according to the method according to the present invention for producing a nano-scale low-dimensional quantum structure, it is possible to form the nano-scale low-dimensional quantum structure in a target area.

Thus, the present invention is applicable to fields such as electronics, information communications, environment energy, biotechnology, medicine, and bioscience, each of which uses nano technology. For example, the present invention can be widely used in controlling structures of a functional material and a structural material in an optical device, an electronic device, and a micro device. Specifically, the present invention can be favorably used in case of forming single-walled carbon nanotubes in a target position in functional materials of an integrated circuit, an electron emissive material, a probe of an STM or the like, a micro machine thin line, a quantum effect thin line, a field effect transistor, a single-electron transistor, a hydrogen absorption material, a bio device, and the like.

1. A method for producing a nano-scale low-dimensional quantum structure, comprising the steps of:
bringing a catalyst which allows the nano-scale low-dimensional quantum structure to be formed thereon into contact with at least part of gas and liquid each of which contains elements constituting the nano-scale low-dimensional quantum structure; and
emitting an electromagnetic wave to the catalyst so as to selectively form the nano-scale low-dimensional quantum structure, having a state density which resonates with a wavelength of the electromagnetic wave, on the catalyst.

2. The method as set forth in claim 1, wherein the electromagnetic wave is locally emitted to a substrate, to which the catalyst has been applied, so as to form the nano-scale low-dimensional quantum structure on the catalyst so that the nano-scale low-dimensional quantum structure is positioned in a target area of the substrate.

3. The method as set forth in claim 1, wherein the electromagnetic wave is emitted to a substrate, on which the catalyst has been patterned in accordance with lithography, so as to form the nano-scale low-dimensional quantum structure on the catalyst so that the nano-scale low-dimensional quantum structure is positioned in a target area of the substrate.

4. The method as set forth in claim 1, wherein the nano-scale low-dimensional quantum structure is capable of being formed at a room temperature.

5. The method as set forth in claim 1, wherein each of the gas and the liquid is a carbon hydride, and the nano-scale low-dimensional quantum structure comprises carbon nanotubes.

6. The method as set forth in claim 1, wherein the catalyst is made of metal or metal oxide.

7. The method as set forth in claim 1, wherein the catalyst is a mixed catalyst obtained by mixing iron, molybdenum, and aluminum oxide.

8. (canceled)

9. The method as set forth in claim 1, comprising the steps of:
disposing a pair of electrodes, at least one of which contains a catalyst, in an electric field;
emitting the electromagnetic wave to the electrode containing the catalyst so as to grow the nano-scale low-dimensional quantum structure between the electrodes;
measuring an electric property between the electrodes; and
controlling electromagnetic wave emission time in accordance with a value obtained by measuring the electric property, wherein
the nano-scale low-dimensional quantum structure is grown while controlling the number of carbon nanotubes which cross-link the electrodes.

10. The method as set forth in claim 1, wherein a laser beam is used as the electromagnetic wave.

11. The method as set forth in claim 10, wherein a light source of the laser beam is Ar laser or He—Cd laser.

12. A method for producing an integrated circuit, comprising the method as set forth in claim 1 as a production step, wherein
the catalyst which allows the nano-scale low-dimensional quantum structure to be formed thereon is brought into contact with at least one of the gas and the liquid each of which contains the element constituting the nano-scale low-dimensional quantum structure, and the electromagnetic wave is locally emitted to an electrode, to which the catalyst has been applied, so as to form the nano-scale low-dimensional quantum structure on the catalyst so that the nano-scale low-dimensional quantum structure is positioned on a target area of the electrode, and the nano-scale low-dimensional quantum structure cross-links the electrodes of the integrated circuit.
